(19) United States
(12) Patent Application Publication
(10) Pub. No.: US 2024/0353502 A1
(43) Pub. Date: Oct. 24, 2024

(54) Machine-Learning-Based Greedy Optimization Mechanism for Reducing Radio-Frequency Tests in Production

(71) Applicant: Google LLC, Mountain View, CA (US)

(72) Inventors: Xianren Wu, San Jose, CA (US); Ying Luo, Cupertino, CA (US); Daniel Minare Ho, New Taipei City (TW); Chung-Cheng Tseng, Taoyuan City (TW); Wenxiao Wang, San Jose, CA (US); Daniel Khuong, Los Gatos, CA (US); Ren-Hua Chang, Taipei City (TW); Chen-Chun Hsiao, New Taipei City (TW); Chien An Hsu, New Taipei City (TW); Hui Peng, Palo Alto, CA (US); Song Liu, Mountain View, CA (US); Yujing Li, Nanjing (CN)

(73) Assignee: Google LLC, Mountain View, CA (US)

(21) Appl. No.: 18/759,308

(22) Filed: Jun. 28, 2024

Related U.S. Application Data
(60) Provisional application No. 63/511,544, filed on Jun. 30, 2023.

(51) Int. Cl. G01R 31/56

(52) U.S. Cl. CPC G01R 31/56

(57) ABSTRACT

This document describes systems and techniques directed at a machine-learning-based greedy optimization mechanism for reducing radio-frequency (RF) tests in production. In aspects, a process capability index is disclosed, the process capability index used to refine a test-set. The test-set includes tests configured to be performed on an electronic device. The process capability index is configured based on upper specification limits and lower specification limits of the electronic device for each test in the test-set, as well as results for each of the tests in the test-set. The process capability index is further configured based on a new upper specification limit and a new lower specification limit of the electronic device for a new test not in the test-set, as well as results for the new test.

### RELATED APPLICATION(S)

This application claims priority to U.S. Provisional Patent Application Ser. No. 63/511,544 filed on Jun. 30, 2023, the disclosure of which is incorporated by reference herein in its entirety.

### BACKGROUND

Manufacturing processes often employ test optimization methods in order to balance testing cost and effectiveness. For example, a production of electronic devices, such as smartphones, undergoes a battery of quality assurance (QA) and control tests in order to ensure reliability, correct functionality, adherence to regulations, etc. Testing each and every smartphone produced yields the highest probability of capturing every device, which may malfunction or otherwise have a defect, but testing every product is prohibitive in terms of speed, expense, and complexity. Manufacturers balance resources with QA while testing the production of electronic devices.

Measurements of test success and cross-applicability aid in balancing QA and production resource management. Process capability indices are configured to capture useful statistics and information regarding QA testing in productions runs. One such index, Critical Process Capability (CpK), is employed prolifically in manufacturing processes. CpK may aid in attempts at QA test optimization and resource use minimization. CpK benefits from upper and lower specification limit calibration when determining mean and mean-deviation values but suffers from unideal scaling with new test-set members. A new method to project the new test-set members onto an existing test-set space would streamline the manufacturing QA process by allowing a lowered resource management without a corresponding loss of QA efficacy.

### SUMMARY

This document describes systems and techniques directed at a machine-learning-based greedy optimization mechanism for reducing radio-frequency (RF) tests in production. In aspects, a process capability index is disclosed, the process capability index used to refine a test-set. The test-set includes tests configured to be performed on an electronic device. The process capability index is configured based on upper specification limits and lower specification limits of the electronic device for each test in the test-set, as well as results for each of the tests in the test-set. The process capability index is further configured based on a new upper specification limit and a new lower specification limit of the electronic device for a new test not in the test-set, as well as results for the new test.

In aspects, a method for identifying test parameters for testing a manufactured electronic device is disclosed. The method includes receiving test parameter data comprising base results of distinct base types of tests for the manufactured electronic device. The method further includes receiving new parameter data comprising a new result of a new type of test for the manufactured electronic device, the new type of test not a member of the base types of tests. In aspects, the method further includes generating a correlation value between the new parameter data and the test parameter data, comparing the correlation value with a threshold value, determining that the correlation value meets or exceeds the threshold value, and constructing a final test type set. In aspects, the final test type set represents a subset of the union between the base types of tests and the new type of test.

According to some examples, the method further includes generating a process capability index, wherein the generation of the correlation value is based on the process capability index value. The process capability index, in some examples, is a critical process capability (CpK) score. According to some examples, the method further includes generating a second process capability index. The second process capability index, in aspects, is generated by updating the CpK score using the new parameter data. In some examples, the determination of the correlation value is further based at least in part on the second process capability index value.

According to some examples, the manufactured electronic device is one of a smartphone, a computer, a smartwatch, true-wireless earbuds, a tablet, smart glasses, hearing aids, AR goggles, or a smart helmet. The comparing of the correlation value with the threshold value, in some examples, is performed by a machine-learned model. The machine learned model, according to some examples, is trained at least in part using a greedy algorithm, with the method further including generating a first process capability index and a second process capability index, where the first process capability index is based on a CpK score and the second process capability index is generated by updating the CpK score using the new parameter data. In some examples, the machine-learned model takes as inputs the test parameter data, the new parameter data, the first process capability index, and the second process capability index.

The details of one or more implementations are set forth in the accompanying Drawings and the following Detailed Description. Other features and advantages will be apparent from the Detailed Description, the Drawings, and the Claims. This Summary is provided to introduce subject matter that is further described in the Detailed Description. Accordingly, a reader should not consider the Summary to describe essential features or limit the scope of the claimed subject matter.

### BRIEF DESCRIPTION OF THE DRAWINGS

Systems and techniques directed at a machine-learning-based greedy optimization mechanism for reducing RF tests in production are described with reference to the following drawings. The same numbers are used throughout the drawings to reference like features and components:

FIG. 1 illustrates an example ideal test set graph;

FIG. 2 illustrates example correlation plots;

FIG. 3 illustrates an example correlation plot for determining vector projection and orthogonality in two dimensions;

FIG. 4 illustrates an example correlation plot for determining vector projection and orthogonality in three dimensions;

FIG. 5 illustrates an example correlation plot between multiple testing parameters;

FIG. 6 illustrates an example escape plot using conditional CpK (CCpK) for a machine-learning-based greedy optimization mechanism for reducing RF tests;

FIG. 7 illustrates an example of a greedy algorithm;

FIG. 8 illustrates an example comparison of a machine-learning-based greedy optimization mechanism for reducing RF tests using CpK vs. CCpK; and

FIG. 9 illustrates an example method for a machine-learning-based greedy optimization mechanism for reducing RF tests.

### DETAILED DESCRIPTION

### Overview

In process improvement efforts, a process capability index or process capability ratio is a statistical measure of process capability. The process capability index can be implemented, for example, to evaluate efficiency of testing of manufacturing products. The process capability index can be thought of as a natural variation for a process, such as deviation from an expected or intended manufacturing outcome for a particular product. The process capability index can be used to compare processes relative to control, such as by using the process capability index to measure how well the natural variations in a produced product are controlled for. Tighter control is correlated with lower manufacturing variations, and thus generating higher QA and product output consistency.

An example process capability index is a Critical Process Capability (CpK). The CpK relies on an upper specification limit (USL) and a lower specification limit (LSL). The CpK relates the process capability to the USL, the LSL, the estimated mean of the process (μ), and the estimated standard deviation (\hat{σ}, which is related to the variance \hat{σ}²). The CpK may be represented mathematically as:

$$CpK = min \{ \frac{\hat{μ} - LSL}{3 \hat{σ}} , \frac{USL - \hat{μ}}{3 \hat{σ}} \} \qquad Eq . 1$$

During manufacturing, there may be more than one quality characteristic of interest in process outcomes. According to some examples, the quality is measured by the joint level of multiple potentially correlated quality characteristics, and thus capability analysis may be based on a multivariate statistical technique. Consider, for example, a multiple quality measure design problem consisting of n performance measures influenced by a common set of possibly independent m design factors. One mathematical representation of a relationship between an ith performance measure and design factors is expressed as:

$${Y}_{i} = {\sum }_{j = 1}^{m} {W}_{i , j} {X}_{j} + {ϵ}_{i} \qquad Eq . 2$$

The variables of Eq. 3 are an ith independent design factor (or underlying failure cause in Manufacturing Tests) Xᵢ, an ith unknown process noise ϵᵢ (modeled, in some examples, as a Gaussian), an ith response Yᵢ, and an ith set of weight factors W_{i,j}. The weight factors W_{i,j} describe, in aspects, the relationship between the ith design factor Xᵢ and the ith response Y ¿. The representation of Eq. 3 may be generalized by expanding the scope from the ith component to the matrix and/or vector representation containing all members Yᵢ, W_{j,i}, Xᵢ, and ϵᵢ of their respective sets. Using this vector and matrix formulation, Eq. 3 may be generalized as:

$$Y = W \cdot X + ϵ \qquad Eq . 3$$

Where Y is all of the responses, X is all of the independent design factors (or underlying failure causes in Manufacturing Tests), e is all of the unknown process noises (in some examples, modeled as Gaussians), and W is a matrix describing the relationship between the design factors X and the responses Y. The relationships, in some examples and as formulated in Eq. 3, are linear. In aspects, Eqs. 1, 2, and 3 allow for multivariate-CpK (MCpK) to be defined as:

$$MCpK = \frac{1}{m} {\prod }_{j = 1}^{m} CpK ( {X}_{j} ) \qquad Eq . 4$$

In some examples, comprehensive tests may be conducted over devices under testing (DUTs) during the manufacturing process to detect if there are any underlying defects and to ensure products to be delivered to customers meet or exceed a threshold quality value. A test outputs vector (such as the responses Y) may be observed, and the underlying failure causes may subsequently be described by X. Considering, for example, Eq. 2, every test output Yᵢ is seen as a linear mixed response W_{i,j}Xᵢ from underlying independent causes together with unknown noise ϵᵢ. In aspects, principal components analysis is used to solve the equation and mathematically establish the mapping between X and Y, where the causes X can be illustrated by mapping Y to the planar space of one eigenvector of the observations. Specifically:

$$\begin{matrix}X = {W}^{T} \cdot Y & Eq . 5 \\ Y = {( W \cdot {W}^{T} )}^{- 1} & Eq . 6 \\ Σ = E ( {Y}^{T} \cdot Y ) = {\sum }_{j} {λ}_{j} \cdot {W}_{j} \cdot {W}_{j}^{T} & Eq . 7\end{matrix}$$

Where W is formulated as one or more matrices by eigenvectors (W₁, W₂, . . . , Wₘ) of the covariance matrices Σ of Y. In some examples, for each cause Xⱼ we have Xⱼ=Wⱼ^{T}·Yⱼ (in some examples, assuming that Y has been normalized to be zero mean and unit variance). This may be represented mathematically as:

$$\begin{matrix}\hat{μ} ( {X}_{j} ) = 0 & Eq . 8 \\ {\hat{σ}}^{2} ( {X}_{j} ) = {λ}_{j} & Eq . 9 \\ {LSL}_{j} = {W}_{j}^{T} \cdot {LSL}_{Y} & Eq . 10 \\ {USL}_{j} = {W}_{j}^{T} \cdot {USL}_{Y} & Eq . 11 \\ CpK ( {X}_{j} ) = min \{ \vert \frac{{LSL}_{j}}{3 √ {λ}_{j}} \vert , \vert \frac{{USL}_{j}}{3 √ {λ}_{j}} \vert \} & Eq . 12\end{matrix}$$

The examples in Eqs. 8 through 12, in aspects, assume Y is joint normal distributed, such as:

$$p ( Y ) \approx {Y}^{T} {Σ}^{- 1} , Y = {\sum }_{j = 1}^{m} \frac{{X}_{j}^{T} \cdot {X}_{j}}{{λ}_{j}} \qquad Eq . 13$$

### Example Optimization

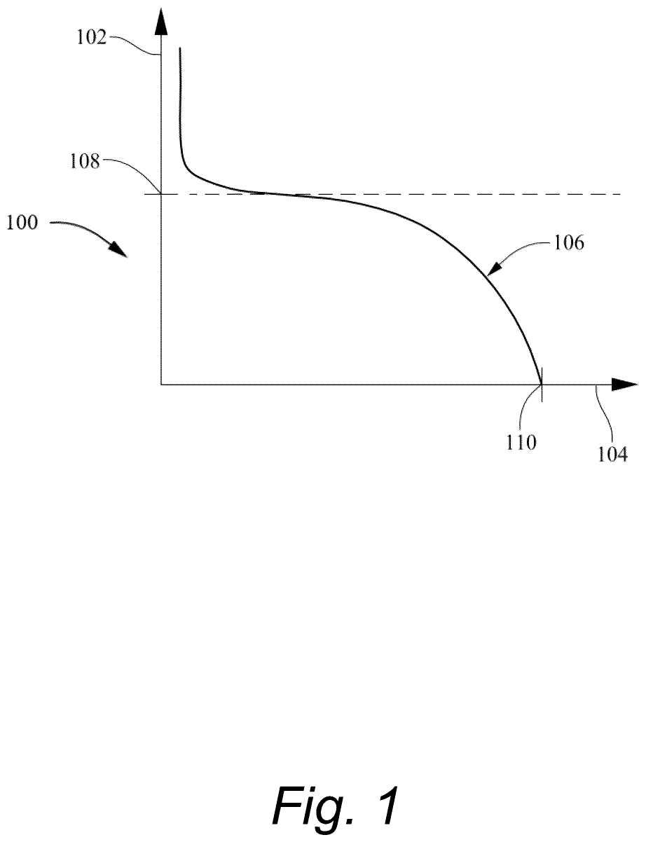

FIG. 1 illustrates an example ideal test set graph 100. A y-axis 102 represents the number of test types performed for a manufacturing process, such as a manufacturing run of smartphones. An x-axis 104 represents a number of failed devices, which are accessible for detection by testing. A trend-line 106 represents a possible trajectory of the number of failed devices as a function of the number of test types performed. A test type is any test configured to find a defect in a manufactured device, a failure in the manufactured device, or a range of operation for the manufactured device. Examples of test types include a test designed to measure a transmission strength of an RF antenna of a communication device and a test designed to give a value for a charge capacity of battery of the manufactured device.

Note the shape of the trend-line 106. Moving from zero failed devices to higher numbers of failed devices along the x-axis 104, the trend-line 106 changes from asymptotically increasing behavior near zero failed devices and zero where it intercepts the x-axis 104. An ideal value 108 is an example of an ideal test type number, which balances manufacturing concerns of test time, cost, and QA for an entire production run. For example, all device failures possible to find with testing is represented as the x-intercept of the trend-line 106 at an intercept point 110. The intercept point 110 may be the total number of failed devices, which are possible to detect by testing. Performing zero tests, of course, will yield a failed device amount of the intercept point 110.

The ideal value 108 may be a value where the best balance between testing costs and QA is within a tolerance range set by a manufacturer. Considering the trend-line 106 near the y-axis 102, it is clear that increasing the number of test types will correlate with lowering the number of failed devices, but the associated costs of testing will summarily increase. The slope of the trend-line 106 near the y-axis 102 illustrates that the increase in testing cost with decreasing failures may be significant. However, there is, in the example test set graph 100, a plateau in the trend-line 106. The plateau, when moving right-to-left along the trend-line 106, leads to a sharp increase as the y-axis 102 is approached. The ideal value 108, in aspects, illustrates a compromise between capturing failed devices with testing and keeping a low associated testing cost.

### Example Correlations

Correlations in manufacturing tests are important to characterize in order to minimize testing types without negatively affecting QA. As in the example ideal test set graph 100, there is a relationship between test types performed and a number of undetected failed devices in a manufacturing run. This section outlines several concepts on correlations relevant to a machine-learning-based greedy optimization mechanism for reducing RF tests in production.

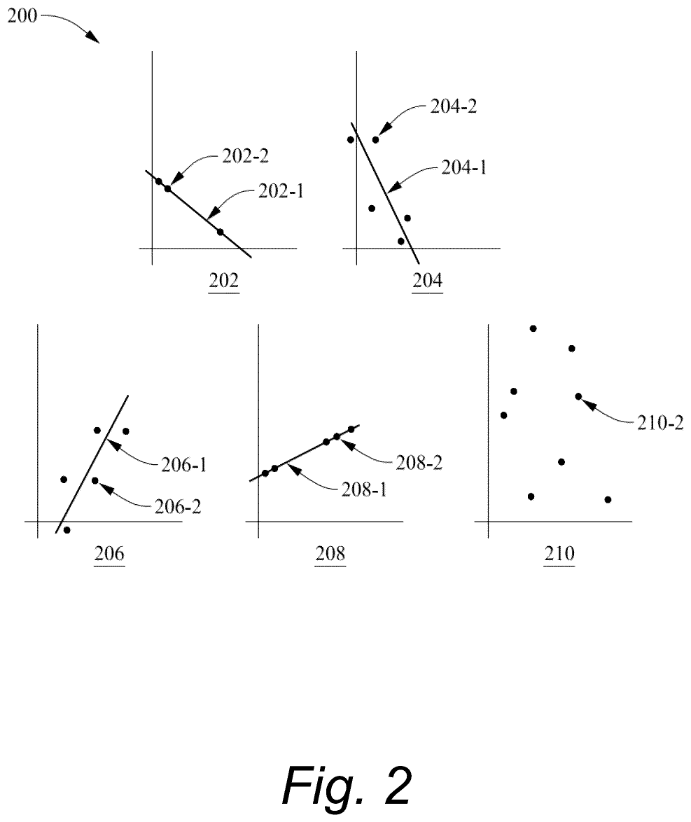

FIG. 2 illustrates example correlation plots 200. Each of plots 202 through 210 show a scatter plot of points. The points may be correlated, with the correlation characterized by a correlation parameter. An example correlation parameter is a Pearson coefficient (ρ). ρ may hold any value between −1 and 1. The closer |ρ| is to 1, the more correlated the points under consideration.

In the plot 202, a fit line 202-1 shows a liner relationship between the points 202-2. The fit line 202-1 shows a complete, negative correlation between the points 202-2, giving:

$$Σ = - 1 \qquad Eq . 14$$

The plot 204 has a fit line 204-1 showing the linear relationship between the points 204-2. It is illustrated that the points have a negative linear relationship, but not a perfect one, giving:

$$- 1 < ρ < 0 \qquad Eq . 15$$

The plot 206 has a fit line 206-1 showing the linear relationship between the points 206-2. It is illustrated that the points have a positive linear relationship, but not a perfect one, giving:

$$0 < ρ < 1 \qquad Eq . 16$$

The plot 208 has a fit line 208-1 showing the linear relationship between the points 208-2. It is illustrated that the points have a perfect and positive linear relationship, giving:

$$ρ = 1 \qquad Eq . 17$$

In some examples, points in a plot may not be correlated in a linear fashion. for example, consider the plot 210. Points 210-2 do not have a clear associated linear trend-line. In this example, ρ=0 and the points 210-2 are said to not be linearly correlated. In aspects, the distribution of the points 210-2 is random (at least linearly, in this example; other correlation schemes exist, which are not linear).

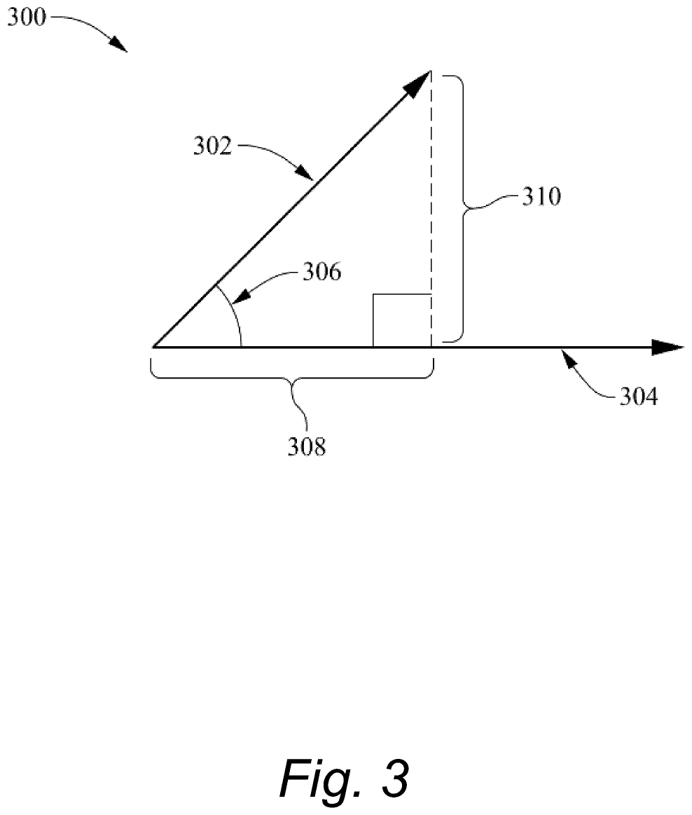

FIG. 3 illustrates an example correlation plot 300 for determining vector projection and orthogonality in two dimensions. A first vector 302 and a second vector 304 are separated by an angle 306 in a two-dimensional space. The two-dimensional space need not be representing two physical dimensions. In some examples, one or more of the two dimensions is a test result dimension. The first vector 302 may be characterized by a component along the second vector, which is a projection component 308, and by a component orthogonal to the second vector 304, which is an orthogonal component 310. In aspects, such componentization is orthogonal, by construction having the projection component 308 at a right angle to the orthogonal component 310.

In aspects, the projection component 308 is a measure of the correlation between the first vector 302 and the second vector 304. Similarly, the orthogonal component 310 is a measure of the lack of correlation (e.g., anticorrelation) between the first vector 302 and the second vector 304. Given a magnitude A for the first vector 302, the magnitude of the projection component 308 may be found using the formula ψₚᵣₒⱼ=A cos θ, where ψ is the first vector 302 and θ is the angle 306. In a similar fashion, the orthogonal component may be found by the formula ψₒᵣₜₕₒ=A sin θ.

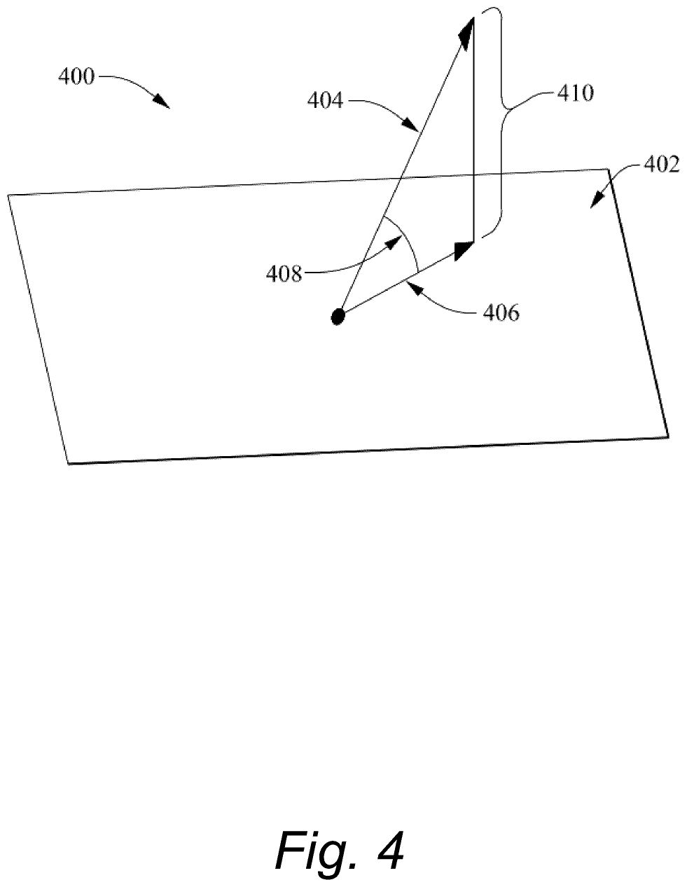

FIG. 4 illustrates an example correlation plot 400 for determining vector projection and orthogonality in three dimensions. The example correlation plot 400 is similar to the example correlation plot 300, but the example correlation plot 400 includes a plane 402. A first vector 404 is correlated with the plane 402, where a projection component is related to an angle of separation 408. Likewise, an orthogonal component 410 is related to the angle 408.

In aspects, the plane 402 represents a multi-dimensional vector space. The dimensions of the three dimensions, including those of the multi-dimensional vector space, need not represent spatial dimensions. In some examples, one or more of the dimensions represent a test space. In some examples, the second vector 304 is a single vector within the plane 402. Other vectors may be used to construct the plane 402 (at least one other vector, for example, aside from the second vector 304 and at an angle 0<θ<π from the second vector 304, not inclusive of 0 and π). In aspects, the projection component 406 is therefore a measure of correlation with the multi-dimensional vector space represented by the plane 402. The orthogonal component 410 is the (scaled) normal to the plane 402, measuring the level of non-correlation (e.g., orthogonality, anti-correlation, etc.) with the plane 402.

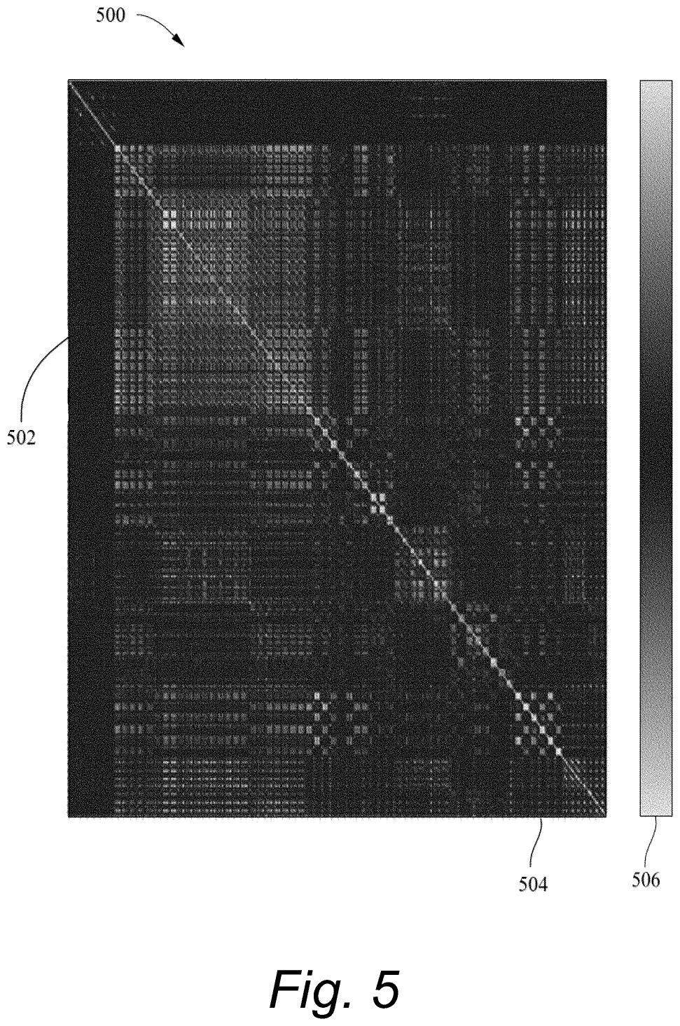

FIG. 5 illustrates an example correlation plot 500 between multiple testing parameters. A y-axis 502 represents an array of different test types, and an x-axis 504 represents the same array of test types. A color-bar 506 (shown in black and white) represents the level of correlation between test types. The example correlation plot 500 has a bright diagonal, representing a 100% self-correlation between tests of the same test type. As the y-axis 502 and the x-axis 504 represent the same test type array, the example correlation plot 500 is symmetrical about the diagonal.

Correlation plots similar to the example correlation plot 500, in some examples, show that certain tests may be superfluous. For example, if two tests show a correlation close to the level of correlation of the diagonal, which is the 100% self-correlation, the two tests do not reveal different information. For example, consider a first manufacturing defect test and a second manufacturing defect test, both effectual to determine a defect in a WiFi antenna of a smartphone. Now consider an additional manufacturing defect test. Suppose the additional test is effectual to determine a defect in a Bluetooth antenna of the smartphone, the second manufacturing defect test is effectual to determine the defect in the WiFi antenna, and the first manufacturing defect test is effectual to find both the defect in the Bluetooth antenna and the defect in the WiFi antenna. In this example, the first manufacturing defect test renders the second manufacturing defect test and the additional manufacturing defect test superfluous if the correlations between the results of the first manufacturing defect test and both the second manufacturing defect test and the additional manufacturing defect test exceed a threshold value.

### Conditional CpK

Measurements such as CpK, in some examples, are used to identify correlations between manufacturing QA test types. In examples where a new test type is added to an existing test type set, the new test type is correlated with the totality of the existing test type set space. As in correlating the first vector 404 with the plane 402 in FIG. 4, projection and orthogonal components for the new test type in relation to the existing test types may be calculated. The previously outlined results Y, in some examples, is the set of existing test types (e.g., measurements of test type results in finding manufacturing defects). When a new test type (e.g., a new observation of a result for the test type on a manufactured product) Yₙ₊₁ is added to the existing test types Y, the projection of the new observation Yₙ₊₁^{proj} to the space spanned by X or Y can be written as:

$$\begin{matrix}{Y}_{n + 1}^{proj} = {\sum }_{j 321}^{m} \frac{{X}_{j}^{T} \cdot {Y}_{n + 1}}{\hat{σ} ( {X}_{j} )} \frac{{X}_{j}}{\hat{σ} ( {X}_{j} )} ( {X}_{j} / \hat{σ} ( {X}_{j} ) ) & Eq . 18 \\ {\hat{σ}}^{2} ( {Y}_{n + 1}^{proj} ) = {\sum }_{j = 1}^{m} {( \frac{{X}_{j}^{T} \cdot {Y}_{n + 1}}{\hat{σ} ( {X}_{j} ) \cdot len ( {X}_{j} )} )}^{2} & Eq . 19 \\ {Y}_{n + 1}^{ortho} = {Y}_{n + 1} - {Y}_{n + 1}^{proj} & Eq . 20 \\ {\hat{σ}}^{2} ( {Y}_{n + 1}^{ortho} ) + {\hat{σ}}^{2} ( {Y}_{n + 1}^{proj} ) = {\hat{σ}}^{2} ( {Y}_{n + 1} ) & Eq . 21\end{matrix}$$

In this case, conditioning on the observations of existing Y is measured by generating a Conditional-CpK (CCpK) for the new observation/test type Yₙ₊₁. This may be represented mathematically as:

$$\begin{matrix}CpK ( {Y}_{n + 1} \vert Y ) ≡ CCpK & Eq . 22 \\ CCpK = min \{ \vert \frac{{LSL}_{n + 1}}{3 \hat{σ} ( {Y}_{n + 1}^{ortho} )} \vert , \vert \frac{{USL}_{n + 1}}{3 \hat{σ} ( {Y}_{n + 1}^{ortho} )} \vert \} & Eq . 23\end{matrix}$$

For dimensions spanned by Y, for example, the projection on each dimension j may be conforming to new limits and/or transformed limits from Y. In such an example, the new limits are estimated from the existing corner points, such as:

$${P}_{corner} ∈ \{ ( {Y}_{0} , {Y}_{1} , ⋯ , {Y}_{n} ) , {Y}_{j} ∈ \{ {LSL}_{j} , {USL}_{j} \} \} \qquad Eq . 24$$

In some examples, YYₙ₊₁^{proj} does not bring additional information if the existing process from Y has already captured all cases within their spanned space, such as:

$$\begin{matrix}{USL}_{n + 1}^{j} = \frac{{USL}_{n + 1}}{\vert \hat{σ} ( {X}_{j} ) \cdot len ( {X}_{j} ) \vert} \geq max \{ {W}_{j}^{T} \cdot {P}_{corner} \} , ∀ P & Eq . 25 \\ {USL}_{n + 1}^{j} = 0.5 * {Σ}_{m} \vert {w}_{j , m} \vert \cdot ( ( sign ( {w}_{j , m} ) + 1 ) \cdot {UDL}_{j} + ( sign ( {w}_{j , m} ) - 1 ) \cdot {LSL}_{j} ) & Eq . 26 \\ {LSL}_{n + 1}^{j} = \frac{{LSL}_{n + 1}}{\vert \frac{{X}_{j}^{T} \cdot {Y}_{n + 1}}{std ( {X}_{j} ) \cdot len ( {X}_{j} )} \vert} \leq min \{ {W}_{j}^{T} \cdot {P}_{corner} \} , ∀ P & Eq . 27 \\ {LSL}_{n + 1}^{j} = 0.5 {Σ}_{m} \vert {w}_{j , m} \vert * ( ( sign ( {w}_{j , m} ) - 1 ) \cdot {USL}_{j} + ( sign ( {w}_{j , m} ) + 1 ) \cdot {LSL}_{j} ) & Eq . 28\end{matrix}$$

In examples where a covariance Σ_{Yall} of all the measurements is normalized with zero mean and unit variance, Σ_{Y,all} is represented by a matrix as:

$${Σ}_{{Y}_{all}} = [ \begin{matrix}{Σ}_{Y} & {Σ}_{Y , {Y}_{n + 1}} \\ {Σ}_{Y , {Y}_{n + 1}} & 1\end{matrix} ] \qquad Eq . 29$$

Given Eq. 29, a variance \hat{σ}²(YYₙ₊₁^{proj}) of YYₙ₊₁^{proj} may be written as:

$${\hat{σ}}^{2} ( {Y}_{n + 1}^{proj} ) = {\sum }_{j = 1}^{m} {( \frac{{W}_{J}^{T} \cdot {Σ}_{Y , Yn + 1}}{\sqrt{{λ}_{j}}} )}^{2} \qquad Eq . 30$$

Further, for a group of tests, the CCpK may be defined as:

$$CCpK ( {Y}_{group} \vert {Y}_{outer} ) = min \{ CpK ( {Y}_{i} \vert {Y}_{outer} ) , ∀ {Y}_{i} ∈ {Y}_{group} \} \qquad Eq . 31$$

During manufacturing testing, an escape rate may measure a probability of a failed device under testing (DUT) not being detected by a test process. When there are no tests, the escape rate may be equivalent to a defect rate from the manufacturing and assembly process. When there are comprehensive tests, the escape rate may be equivalent to the defect rate when none of the tests are effective to detect the failure. Mathematically, the escape rate may be written as:

$$\begin{matrix}P ( escape , {Y}_{i} , ∀ i ) ≡ {P}_{e} & Eq . 32 \\ {P}_{e} = P ( {Y}_{i} ∈ ( {LSL}_{i} , {USL}_{i} ) , ∀ i , {DUT}_{fail} ) & Eq . 33 \\ {P}_{e} = P ( {DUT}_{fail} \vert {Y}_{i} ) ∈ ( {LSL}_{i} , {USL}_{i} ) , ∀ i ) ) \cdot P ( {Y}_{i} ∈ ( {LSL}_{i} , {USL}_{i} ) , ∀ i ) & Eq . 34 \\ {P}_{e} \leq P ( {DUT}_{fail} ) \cdot P ( {Y}_{i} ∈ ( {LSL}_{i} , {USL}_{i} ) ∈ i ) & Eq . 35\end{matrix}$$

For example, given a set of tests {Yᵢ}, i∈{1, . . . , n} with addition of the new observation Yₙ₊₁, the reduction in the escape rate may be written as:

$$\begin{matrix}P ( escape , {Y}_{i} ∀ i ∈ \{ 1 , ⋯ , n \} ) - P ( escape , {Y}_{i} ∀ i ∈ \{ 1 , ⋯ , n - 1 \} ) ≡ {P}_{e , n} & Eq . 36 \\ {P}_{e , n} = c \cdot P ( {Y}_{i} ∈ ( {LSL}_{i} , {USL}_{i} ) , ∀ i ∈ \{ 1 , ⋯ , n \} , {Y}_{n + 1} ∉ ( {LSL}_{n + 1} , {USL}_{n + 1} ) ) & Eq . 37\end{matrix}$$

Using the definitions and formulations of Eqs. 32 through 34, CpK, MCpK, and CCpK may be approximated as:

$$\begin{matrix}CpK \approx \frac{1}{3} {Φ}^{- 1} ( 1 - max ( {P}_{lower fail} , {P}_{upper fail} ) ) & Eq . 38 \\ MCpK \approx \frac{1}{3} {Φ}^{- 1} ( 1 - \frac{{P}_{fail}}{2} ) & Eq . 39 \\ CCpK \approx \frac{1}{3} {Φ}^{- 1} ( 1 - \frac{P ( escape , {Y}_{n + 1} )}{2} ) & Eq . 40\end{matrix}$$

Where Eqs. 35 through 40 assume, in aspects, a suitable function Φ. Eq. 40 may be rewritten, given one sided limits, as:

$$CCpK \approx \frac{1}{3} {Φ}^{- 1} ( 1 - P ( escape , {Y}_{n + 1} ) ) \qquad Eq . 41$$

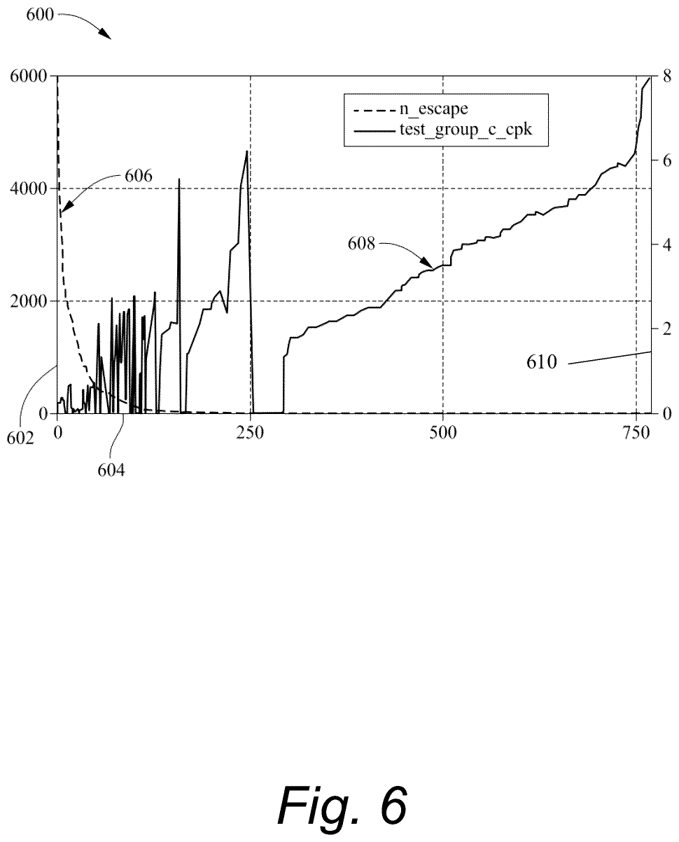

FIG. 6 illustrates an example escape plot 600 using CCpK for a machine-learning-based greedy optimization mechanism for reducing RF tests. A left y-axis 602 represents a number of escaped DUTs. An x-axis 604 represents the number of test types performed. A dashed trend-line 606 represents the number of escaped DUTs per test type number. A solid trend-line 608 represents the CCpK value per test-type number (shown by a right y-axis 610).

A first portion of the example escape plot 600 prior to an x value of 250 shows results for required testing, which may be due to regulations, determined best practices, or other reasons. The CCpK value fluctuates in the first portion. A second portion, starting at around x=300, shows the CCpK values rising without a subsequent rise in the escape values. The CCpK values rise in the second portion with test-type number, showing a correlation value between newly added test-types and the existing test-type space. The CCpK values, in some examples, are reliably sensitive to relevant correlations, showing that increasing test-type number over a certain amount does not net greater escape capture.

### Example Greedy Optimization

Machine-learning (ML) may be used to help determine a test-type number, as well as the members of a final test-type set. In aspects, a back-propagation-based ML algorithm may be counterproductive in optimization schemes employing ML for a machine-learning-based greedy optimization mechanism for reducing RF tests. For example, a multi-level perceptron (MLP) model using supervised data first fits a test data set, then characterizes a goodness of fit (e.g., using a loss function) before fitting again. In a manufacturing production run, once the testing is complete, devices are ready for shipment. Testing the devices again would add time, expense, complexity, and/or other effects, which may be outside of limits set by the manufacturer.

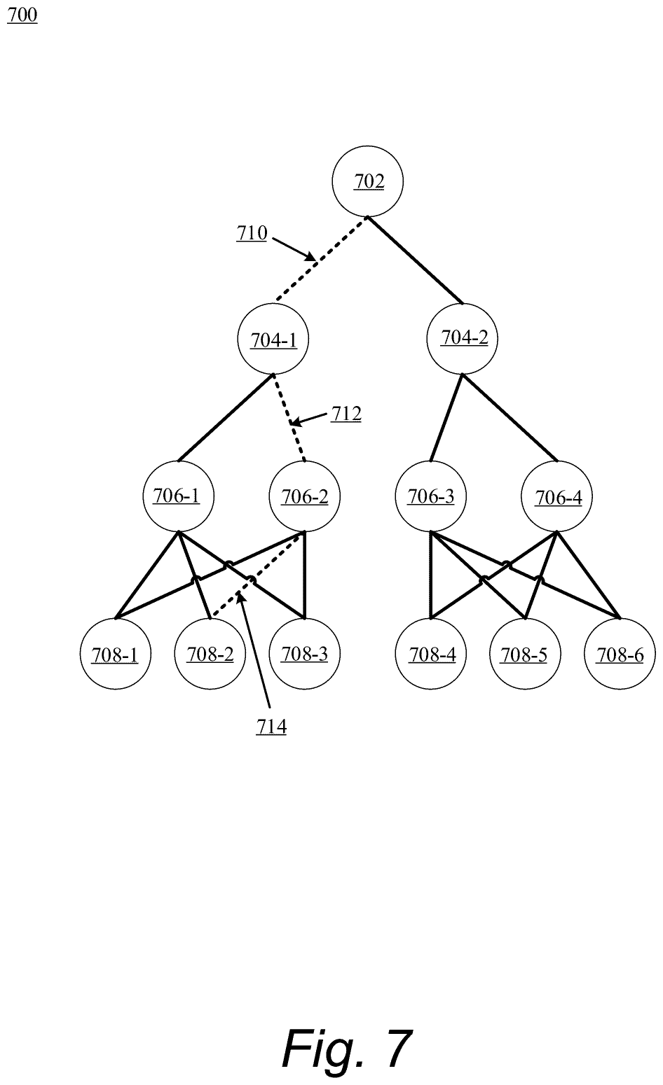

FIG. 7 illustrates an example of a greedy algorithm 700. The example greedy algorithm 700 starts at a point 702, with paths leading from the point 702. The example greedy algorithm 700 chooses the most-ideal path, given the known parameters at the point 702. From the point 702, points 704-1 and 704-2 are accessible. From the point 704-1, points 706-1 and 706-2 are accessible, while the point 704-2 has points 706-3 and 706-4 accessible.

In some examples, points in one row have access to a same set of points in a next row. Consider the points 706-1 and 706-2. The point 706-1 has points 708-1 through 708-3 accessible, which are the same points accessible to the point 706-2. Each connecting line represents both a causal connection and a temporal connection. For example, going from the point 702 to the point 704-1 via a connection 710 implies that the point 704-1 is causally connected to the point 702 and that the point 704-1 comes after the point 702 (e.g., in time or order of operations).

The example greedy algorithm 700 chooses the best path given at the time of each point it is on, without referencing a future point. For example, at the point 702 the example greedy algorithm 700 selects the path 710 to the point 704-1. The decision to move through the path 710 to the point 704-1 does not rely on information in the points 706-1 through 706-4, nor in the points 708-1 through 708-6. The example greedy algorithm then determines that a path 712, from the point 704-1 to the point 706-2, is the best choice. Finally, the example greedy algorithm 700 selects a path 714 from the point 706-3 to the point 708-2. At each step, the example greedy algorithm makes the determination of which path is best based on its current fit; the example greedy algorithm 700 does not use future information to affect past information (e.g., making the decision to take the path 712 based on information contained by the point 708-2).

Due to the non-back-propagating methodology of the example greedy algorithm 700, a final path (in FIG. 6 represented by the paths 710, 712, and 714) may not be an ideal path. It is possible, in aspects and generally, that the final path is not as efficient as another accessible path. However, due to the aforementioned limitation of the manufacturing process where a back-propagation style fitting would require multiple, redundant testing, the example greedy algorithm 700 may simply pick the best choice at any given point.

As an input parameter for a ML model using a greedy algorithm (e.g., the example greedy algorithm 700), CCpK may be a natural parameter to use for an input, at least in part. As CCpK, in some examples, updates at every new test-type employed, correlations found by CCPK may work along with a structure of the greedy algorithm to provide a finer fit and/or prediction for a next path to take. Other inputs may also be used, such as a test time, a total number of test-types in a current test-set, CpK, etc. Additionally or alternately, CCpK may be used to determine if an existing test-type in the current test-type set may be eliminated with a greater efficiency expectation, given the new test-type.

In practice, implementing the greedy algorithm may include several of the concepts discussed in this disclosure. Additionally or alternately, in some examples, clustering algorithms, such as Density-Based Spatial Clustering of Applications with Noise (DBSCAN) or K-Means++, may be pre-applied to identify groups of clusters with a low intra-cluster correlation, a mathematical independence, or weak correlations. A process reduction within a group of correlated processes may be pursued as a greedy process. By way of example, the greedy process starts with an empty set of test items, then chooses the test item with smallest CpK as a seed. For each iteration, the greedy process chooses to add the test item with one or more of a largest reduction in escape probability, a minimum CCpK, or a largest variance on orthogonal components (e.g., using a Z-score based approach with all tests normalized). A growth of the test set may be stopped upon reaching one or more of a minimum threshold on escapes, a minimum CCpK, or a maximum threshold on variances.

In some examples, the greedy process chooses to remove the test item for each iteration with one or more of a minimum reduction in escape probability, a largest CCpK, or a minimum variance on orthogonal component. A reduction of the test set may be stopped upon reaching one or more of a largest threshold on escapes, the minimum CCpK, or a minimum threshold on variances.

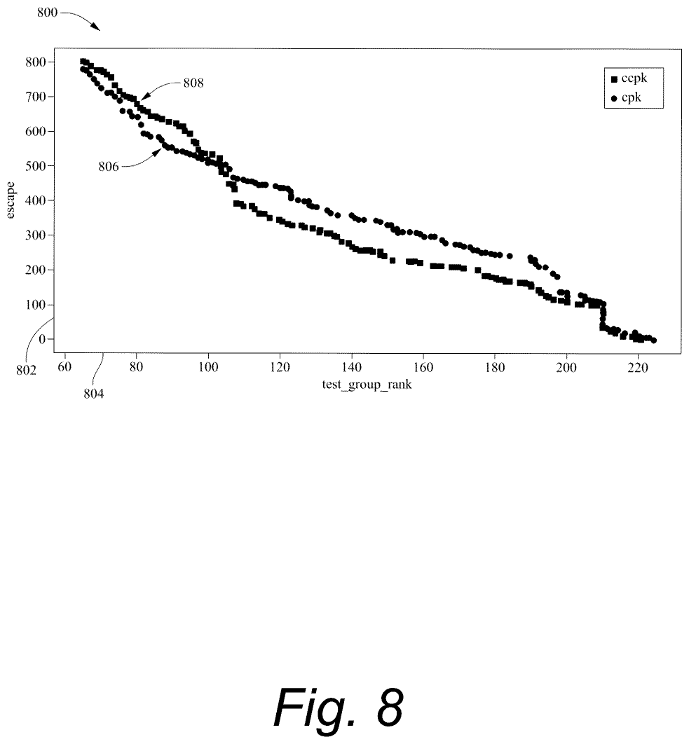

FIG. 8 illustrates an example comparison 800 of a machine-learning-based greedy optimization mechanism for reducing RF tests using CpK vs. CCpK. A y-axis 802 represents the number of escaped DUTs. An x-axis 804 represents the test group rank, which is a measure of the test-type set given an increasing number of test-types. The circle points 806 represent testing using a greedy algorithm with CpK as an input, and the square points 808 represent testing using a greedy algorithm with CCpK as the input. Though other input types may be used, the example comparison 800 shows the difference when CCpK is substituted for CpK.

It can be seen that, at a low test group rank region, the circle points 806 representing the CpK input are lower than the square points 808 representing the CCpK input, indicating less DUT escapes for the CpK input in the low test group rank region. At a high test group rank region, the circle points 806 and the square points 808 perform similarly to one another. In a central region of the test group ranks, such as in the range of test group ranks from 110 through 200, the CCpK input consistently measures lower along the y-axis 802 than the CpK input, indicating that the CCpK input corresponds with lower DUT escapes than the CpK input in the central region.

### Example Method

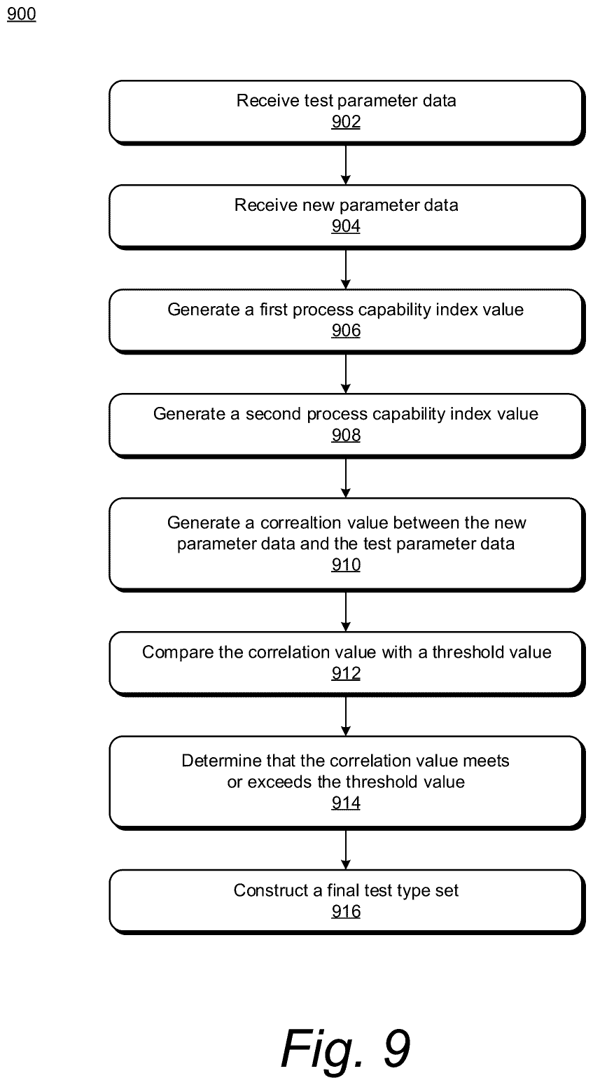

FIG. 9 illustrates an example method 900 for a machine-learning-based greedy optimization mechanism for reducing RF tests. The example method 900 may be used for testing a manufactured electronic device. The manufactured electronic device may be one of a smartphone, a computer, a smartwatch, true-wireless earbuds, a tablet, smart glasses, hearing aids, AR goggles, or a smart helmet. Other types of electronic devices not listed may also benefit from the example method 900.

At 902, test parameter data is received. The test parameter data includes base results of base types of tests for the manufactured electronic device. The base types of tests, in some examples, include RF tests, such as radiation tests, reception tests, or other tests related to RF components of the manufactured electronic device. Additionally or alternately, tests of other components may be included in the base types of tests, such as battery tests and non-RF radiation tests.

At 904, new parameter data is received. The new parameter data includes a new result of a new type of test for the manufactured device. The new type of test is not a member of the base type of tests. The new type of test may test related components of the manufactured electronic device as one or more of the base types of tests.

At 906, a first process capability index value is generated. In some examples, generating the first process capability index value involves generating a CpK value. At 908, a second process capability index value is generated. The second process capability index value is generated by updating the first process capability index value using the new parameter data. In the example where the first process capability index value is a CpK value, the second process capability index value may be a CCpK value.

At 910, a correlation value between the new parameter data and the test parameter data is generated. In some examples, the generation of the correlation value is based on the first process capability index value. In some examples, the generation of the correlation value is based on the second process capability index value.

At 912, the correlation value is compared with a threshold value. In some example, the comparing of the correlation value with the threshold value is performed by a machine-learned (ML) model. According to some examples, the ML model is trained, at least in part, using a greedy algorithm. The machine learned model, in some examples, takes as an input one or more of the test parameter data, the new parameter data, the first process capability index, or the second process capability index.

At 914, it is determined that the correlation value meets or exceeds the threshold value. In some examples, the determination that the correlation value meets or exceeds the threshold value is performed by the ML model. At 916, a final test type set is constructed. The final test type set represents a subset of the union between the base types of tests and the new type of test. This union may be represented mathematically as:

$$F ϵ \{ B ⋃ N \} \qquad Eq . 42$$

F in Eq. 39 represents the final test type set, B represents the base types of tests, and N represents the new type of test. While F is depicted in Eq. 39 as belonging to a set of the union between B and N, this should not be understood as F including all members of B and N (though that is allowable), but rather as a constraint upon the scope of F. It should also be understood that {B∪N} is itself an available subset of {B∪N}.

### Example Devices

The examples disclosed herein of a machine-learning-based greedy optimization mechanism for reducing RF tests may be utilized on a variety of device types. For example, applying a machine-learning-based greedy optimization mechanism for reducing RF tests to a manufacturing run of smartphones. Other devices may equally employ a machine-learning-based greedy optimization mechanism for reducing RF tests, such as a desktop computer, a laptop computer, a smartwatch, earbuds, smart glasses, a smart helmet, a tablet device, a hub device, or other electronic devices not listed.

In general, an example electronic device that can implement a machine-learning-based greedy optimization mechanism for reducing RF tests in accordance with one or more described aspects. The electronic device may be implemented as any one of or a combination of a fixed, mobile, stand-alone, or embedded device; in any form of a consumer, computer, portable, user, server, communication, phone, navigation, gaming, audio, camera, messaging, media playback, and/or other type of electronic device.

The electronic device can include one or more communication transceivers that enable wired and/or wireless communication of device data, such as received data, transmitted data, or other information. Example communication transceivers include NFC transceivers, wireless personal area network (PAN) (WPAN) radios compliant with various IEEE 802.15 (Bluetooth™) standards, wireless local area network (LAN) (WLAN) radios compliant with any of various IEEE 802.11 (Wi-Fi™) standards, wireless wide area network (WAN) (WWAN) radios (e.g., those that are 3GPP-compliant) for cellular telephony, wireless metropolitan area network (MAN) (WMAN) radios compliant with various IEEE 802.16 (WiMAX™) standards, infrared (IR) transceivers compliant with an Infrared Data Association (IrDA) protocol, and wired local area network (LAN) Ethernet transceivers.

The electronic device may also include one or more data input ports via which any type of data, media content, and/or other inputs can be received, such as user-selectable inputs, messages, applications, music, television content, recorded video content, and any other type of audio, video, and/or image data received from any content and/or data source. The data input ports may include USB ports, coaxial cable ports, fiber optic ports for optical fiber interconnects or cabling, and other serial or parallel connectors (including internal connectors) for flash memory, DVDs, CDs, and the like. These data input ports may be used to couple the electronic device to components, peripherals, or accessories such as keyboards, microphones, cameras, or other sensors.

The electronic device of this example includes at least one processor (e.g., any one or more of application processors, microprocessors, digital-signal processors (DSPs), controllers, and the like), which can include a combined processor and memory system (e.g., implemented as part of an SoC), that processes (e.g., executes) computer-executable instructions to control operation of the device. The processor may be implemented as an application processor, embedded controller, microcontroller, security processor, and the like. Generally, a processor or processing system may be implemented at least partially in hardware, which can include components of an integrated circuit or on-chip system, a digital-signal processor (DSP), an application-specific integrated circuit (ASIC), a field-programmable gate array (FPGA), a complex programmable logic device (CPLD), and other implementations in silicon and/or other materials.

Alternatively or additionally, the electronic device can be implemented with any one or combination of electronic circuitry, which may include software, hardware, firmware, or fixed logic circuitry that is implemented in connection with processing and control circuits. This electronic circuitry can implement executable or hardware-based modules, such as through processing/computer-executable instructions stored on computer-readable media, through logic circuitry and/or hardware (e.g., such as an FPGA), and so forth.

The electronic device can include a system bus, interconnect, crossbar, or data transfer system that couples the various components within the electronic device. A system bus or interconnect can include any one or a combination of different bus structures, such as a memory bus or memory controller, a peripheral bus, a universal serial bus, and/or a processor or local bus that utilizes any of a variety of bus architectures.

The electronic device also includes one or more memory devices that enable data storage, examples of which include random access memory (RAM), non-volatile memory (e.g., read-only memory (ROM), flash memory, EPROM, and EEPROM), and a disk storage device. Thus, the memory device(s) can be distributed across different logical storage levels of a system as well as at different physical components. The memory device(s) provide data storage mechanisms to store the device data, other types of code and/or data, and various device applications (e.g., software applications or programs). For example, an operating system can be maintained as software instructions within the memory device and executed by the processor.

In some implementations, the electronic device also includes an audio and/or video processing system that processes audio data and/or passes through the audio and video data to an audio system and/or to a display system (e.g., a video buffer or a screen of a smartphone or camera). The audio system and/or the display system may include any devices that process, display, and/or otherwise render audio, video, display, and/or image data. Display data and audio signals can be communicated to an audio component and/or to a display component via an RF (radio frequency) link, S-video link, HDMI (high-definition multimedia interface), composite video link, component video link, DVI (digital video interface), analog audio connection, or other similar communication link, such as a media data port. In some implementations, the audio system and/or the display system are external or separate components of the electronic device. Alternatively, the display system can be an integrated component of the example electronic device, such as part of an integrated touch interface.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations directed at a machine-learning-based greedy optimization mechanism for reducing radio-frequency (RF) tests in production have been described in language specific to certain features and/or methods, the subject of the appended claims is not necessarily limited to the specific features or methods described. Rather, the specific features and methods are disclosed as example implementations directed at a machine-learning-based greedy optimization mechanism for reducing radio-frequency (RF) tests in production.

What is claimed is:

1. A method for identifying test parameters for testing a manufactured electronic device, the method comprising:
receiving test parameter data comprising base results of base types of tests for the manufactured electronic device;
receiving new parameter data comprising a new result of a new type of test for the manufactured electronic device, the new type of test not a member of the base types of tests;
generating a correlation value between the new parameter data and the test parameter data;
comparing the correlation value with a threshold value;
determining that the correlation value meets or exceeds the threshold value; and
constructing a final test type set, the final test type set representing a subset of the union between the base types of tests and the new type of test.

2. The method of claim 1, further comprising generating a process capability index, wherein the generation of the correlation value is based on the process capability index value.

3. The method of claim 2, wherein the process capability index is a critical process capability (CpK) score.

4. The method of claim 3, further comprising generating a second process capability index value, wherein:
the second process capability index is generated by updating the CpK score using the new parameter data; and
the generation of the correlation value is further based at least in part on the second process capability index value.

5. The method of claim 1, wherein the manufactured electronic device is one of:
a smartphone;
a computer;
a smartwatch;
true-wireless earbuds;
a tablet;
smart glasses;
hearing aids;
AR goggles; or
a smart helmet.

6. The method of claim 1, wherein the comparing of the correlation value with the threshold value is performed by a machine-learned model.

7. The method of claim 6, wherein the machine learned model is trained at least in part using a greedy algorithm.

8. The method of claim 6, further comprising generating a first process capability index and a second process capability index, wherein:
the first process capability index is based on a CpK score;
the second process capability index is generated by updating the CpK score using the new parameter data; and
the machine-learned model takes as inputs:
the test parameter data;
the new parameter data;
the first process capability index; and
the second process capability index.
